(19) United States
(12) Patent Application Publication
(10) Pub. No.: US 2013/0292530 A1
(43) Pub. Date: Nov. 7, 2013

(54) STYLUS HOLDER

(71) Applicants: Dat Dang, Westminster, CA (US); Deborah L. Michelle, Mission Viejo, CA (US)

(72) Inventors: Dat Dang, Westminster, CA (US); Deborah L. Michelle, Mission Viejo, CA (US)

(73) Assignee: TARGUS GROUP INTERNATIONAL, INC., Anaheim, CA (US)

(21) Appl. No.: 13/464,617

(22) Filed: May 4, 2012

(51) Int. Cl. H05K 7/00

(52) U.S. Cl. 248/229.2

(57) ABSTRACT

A stylus holder attaches to an electronic device and holds a stylus. The stylus holder may comprise a pair of device clasps to frictionally hold to the electronic device. A stylus clasp for holding a stylus may be on one of the device clasps. The device clasps may be connected to one another by a band. In some embodiments, the band may be an elastomeric ribbon.

### TECHNICAL FIELD

This application relates to stylus holders.

### BRIEF DESCRIPTION OF THE DRAWINGS

FIG. 1 is a side view of a stylus holder.

FIG. 2 is a front view of the stylus holder of FIG. 1.

FIG. 3A-B are back and front views of the stylus holder of FIG. 1 attached to a tablet and holding a stylus.

### DETAILED DESCRIPTION OF PREFERRED EMBODIMENTS

Many tablets, laptop PCs, smart phones, and other electronic devices have touch screens that can receive input from an object touching their display. Although a finger can be used to touch the display, a stylus may allow for better control when writing, drawing, or the like. Unfortunately, electronic devices often do not have a place to secure a stylus. Also, styluses may vary in size depending on manufacturer. A stylus holder that can be secured to one or more electronic devices may allow for convenient storage of a stylus.

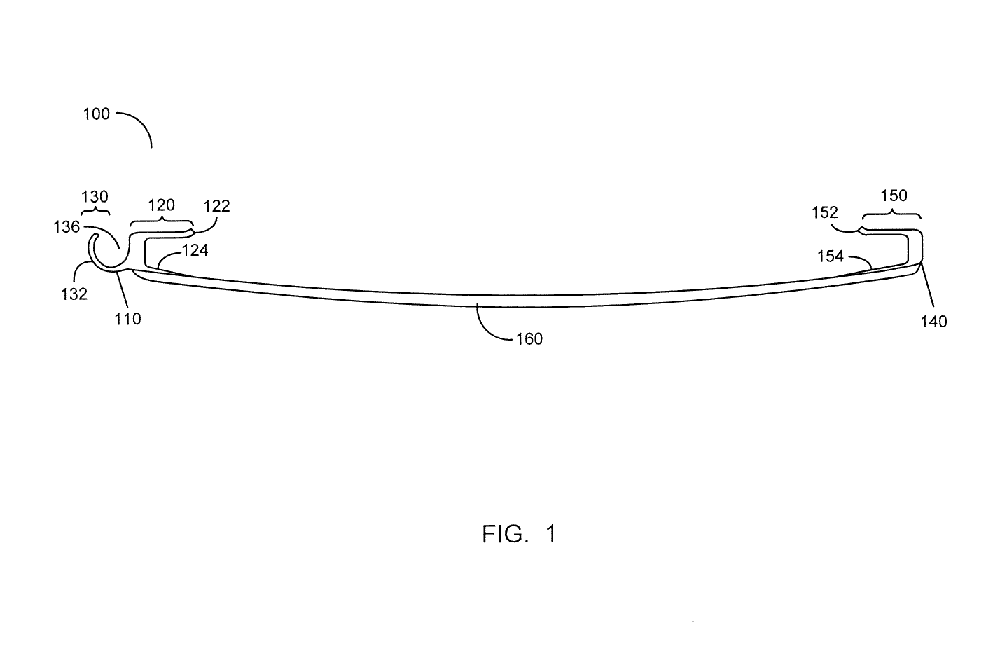

FIG. 1 is a side view of a stylus holder 100. The stylus holder 100 comprises two clasping members 110, 140. The first clasping member 110 comprises a device clasp 120 and a stylus clasp 130. The second clasping member 140 comprises a device clasp 150. The two clasping members 110, 140 are connected to one another by a band 160.

In the illustrated embodiment, the device clasps 120, 150 are substantially U-shaped and each comprise two fingers 122, 124, 152, 154 for engaging with the device. In other embodiments, the device clasps 120, 150 may be C-shaped, J-shaped, or V-shaped. The fingers 122, 124, 152, 154 of each clasp may be parallel, or they may slant outwardly or inwardly. In some embodiments, the size and shape of the device clasps 120, 150 and the angle of the fingers 122, 124, 152, 154 may selected according to the size and shape of one or more electronic devices with which the stylus holder 100 is designed to interface. The width of the device clasp opening at a particular depth may be selected to be as wide as, slightly narrower than, or slightly wider than the width of the device.

The fingers 122, 124, 152, 154 may be selected to be a stiff material that is slightly deformable but returns to its original shape. The deformation of the fingers 122, 124, 152, 154 by an electronic device would then cause the fingers 122, 124, 152, 154 to exert a frictional force against the electronic device. The frictional force would secure the stylus holder to the electronic device. In some embodiments, the device clasps 120, 150 may be a polymer, such as plastic or rubber. In other embodiments, the device clasps 120, 150 may be a metal, such as stainless steel. The device clasps 120, 150 may have cloth, felt, or the like on the inside of the fingers 122, 124, 152, 154 for materials that may scratch or damage the electronic device.

In the illustrated embodiment, the stylus clasp 130 is substantially C-shaped with one finger 132 for engaging the stylus. The stylus clasp 130 may also be J-shaped, O-shaped, U-shaped, V-shaped, or polygon-shaped. For O-shaped and polygon-shaped stylus clasps, the stylus may be slid into stylus clasp from its side. The stylus clasp 130 and device clasp 120 may have openings on opposite sides, resulting in an H-shaped clasping member 110. An opening 136 of the stylus clasp 130 faces the front of the stylus holder 100. In other embodiments, the stylus clasp 130 may face the top, bottom, or back of the stylus holder 100. The illustrated stylus clasp 130 is located on top of the device clasp 120, but in other embodiments, it may be located on front of the front finger 122 or on the back of the back finger 124.

The stylus clasp 130 may also be a stiff, elastically deformable material. The stylus clasp 130 may be a polymer, such as rubber or plastic, or a metal, such as stainless steel. In some embodiments, the clasping member 110 is entirely made from a single material, but more than one material is possible in other embodiments. A circumference of the stylus clasp 130 may be selected to be slightly smaller than a circumference of a stylus. The stylus clasp 130 would then exert a frictional force and mechanical force based on shape against a stylus that was inserted. In other embodiments, the circumference of the stylus clasp 130 is larger than the circumference of the stylus and only the shape of the stylus clasp 130 retains the stylus. The size and shape of the stylus clasp 130 may be selected based on a size and shape of one or more styluses the stylus holder 100 is designed to hold.

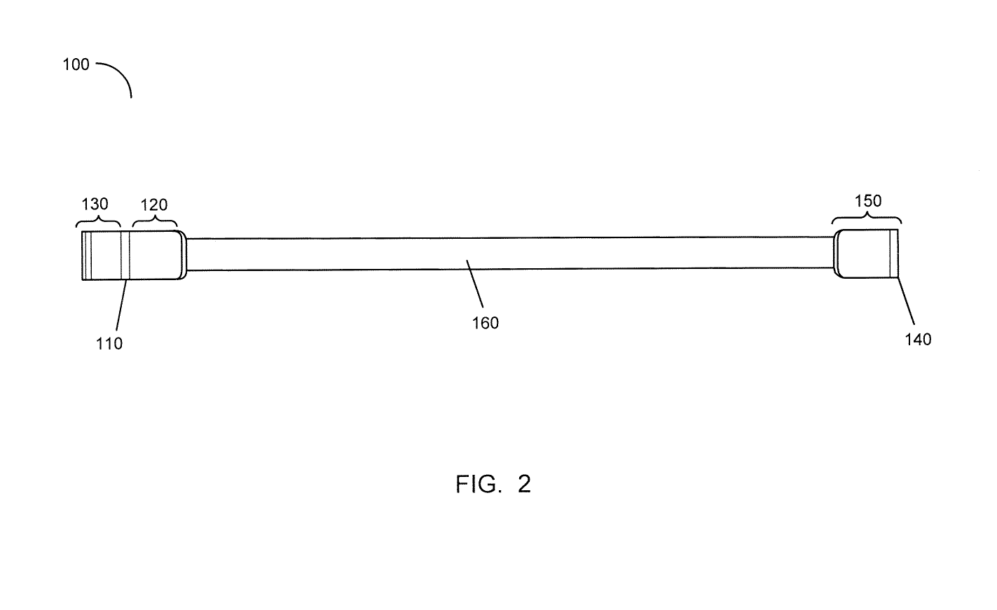

FIG. 2 is a front view of the stylus holder 100. The illustrated band 160 is a ribbon of elastomeric material. The band 160 may allow the stylus holder 100 to be folded or crumpled to a reduced height for storage. The band 160 may be woven from elastomeric threads. The elastomeric material may be a polymer, such as nylon, rubber, or polypropylene. In other embodiments, the band 160 may be stiff or made from a non-elastic material. In those embodiments, the band may be a polymer, such as an inelastic plastic, or a metal, such as stainless steel. The stylus holder 100 may be made entirely of one material in some embodiments. For elastomeric bands 160, the device clasps 120, 150 may be stretched around an electronic device. For inelastic materials, the device clasps 120, 150 may be slid sideways on to the electronic device.

Although the illustrated band 160 is a ribbon with a width much larger than its depth, other shaped bands are possible. For example, the band 160 may comprise one or more cords with approximately equal widths and depths. In some embodiments, one or both clasping members 110, 140 may be slideably or removeably coupled to the band 160, such as using a frictional binding. The stylus holder 100 may then be adjusted to fit electronic devices of varying sizes. In other embodiments, ends of the band 160 are permanently affixed to the clasping members 110, 140, such as with an adhesive. In the illustrated embodiment, the band 160 is affixed to the back of the clasping members 110, 140. In other embodiments, the band 160 may be affixed in other locations. There may also be more than one band, such as a band attached to the back of the clasping members and a band attached to the front of the clasping members.

The clasping members 110, 140 can be ¼″, ½″, ¾″, or 1″ wide. In some embodiments, the device clasps 120, 150 are different widths than the stylus clasp 130. The device clasps may be more than 1″ to increase frictional engagement with the electronic device with a stylus clasp that is still ¼″, ½″, ¾″, or 1″ wide. The device clasps 120, 150 may also be different widths from each other.

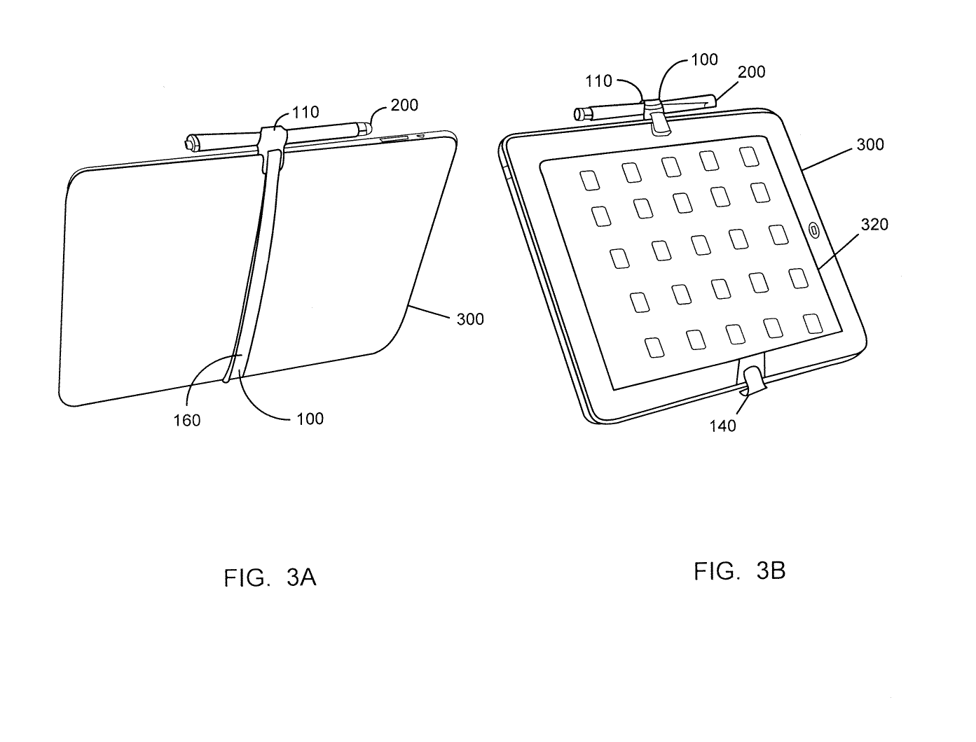

FIG. 3A-B are front and back views of the stylus holder 100 attached to a tablet 300 and holding a stylus 200. In some embodiments, the stylus holder 100 may have a height slightly smaller than the length of the electronic device 300 it is gripping. This results in stretching of the band 160, which provides tension on the clasping member 110, 140 holding them in place. In other embodiments, the height may be approximately the same as the length of the electronic device 300. In the illustrated embodiment, the stylus holder 100 has a height selected so the stylus holder 100 may grip the smaller dimension of the tablet's 300 face. In other embodiments, the stylus holder 100 may have a height selected so the stylus holder 100 may grip the larger dimension of the tablet's 300 face. Because the band 160 is behind the tablet, it does not obscure a display area 320 of the tablet 300. The stylus 200 is held adjacent to the display area 320 of the tablet, making it easily accessible when interacting with the tablet 300.

It will be obvious to those having skill in the art that many changes may be made to the details of the above-described embodiments without departing from the underlying principles of the invention. The scope of the present invention should, therefore, be determined only by the following claims.

1. A stylus holding apparatus comprising:
a first clasping member comprising a first device clasp and a stylus clasp, wherein the stylus clasp is C-shaped;
a second clasping member comprising a second device clasp; and
a band, wherein the band is affixed to the first clasping member and the second clasping member.

2. The stylus holding apparatus of claim 1, wherein the band is an elastomeric ribbon.

3. The stylus holding apparatus of claim 1, wherein the first clasping member is a stiff, elastically deformable material.

4. The stylus holding apparatus of claim 1, wherein the stylus clasp comprises an opening, and wherein the opening is on an opposing side of the first clasping member relative to the affixment between the band and the first clasping member.

5. The stylus holding apparatus of claim 1, wherein the stylus clasp is on an opposing side of the first clasping member relative to an opening of the first device clasp.

6. The stylus holding apparatus of claim 1, wherein the band is permanently affixed to the first and second clasping members.

7. The stylus holding apparatus of claim 1, wherein the band is at least one of slideably affixed and removeably affixed to the first and second clasping members.

8. The stylus holding apparatus of claim 1, wherein the first and second device clasps are U-shaped.

9. The stylus holding apparatus of claim 1, wherein the first and second clasping members have a width of half of an inch.

10. A stylus holding apparatus comprising:
a first clasping member comprising a first device clasp and a stylus clasp;
a second clasping member comprising a second device clasp; and
a band,
wherein the band is affixed to the first clasping member and the second clasping member, and
wherein the band is an elastomeric ribbon.

11. The stylus holding apparatus of claim 10, wherein the stylus clasp is C-shaped.

12. The stylus holding apparatus of claim 10, wherein the first clasping member is a stiff, elastically deformable material.

13. The stylus holding apparatus of claim 10, wherein the first and second clasping member further comprise a device interface, wherein the device interface comprises at least one of felt and cloth.

14. The stylus holding apparatus of claim 10, wherein the stylus clasp comprises an opening, and wherein the opening is on an opposing side of the first clasping member relative to the affixment between the band and the first clasping member.

15. The stylus holding apparatus of claim 10, wherein the stylus clasp is on an opposing side of the first clasping member relative to an opening of the first device clasp.

16. The stylus holding apparatus of claim 10, wherein the band is permanently affixed to the first and second clasping members.

17. The stylus holding apparatus of claim 10, wherein the band is at least one of slideably affixed and removeably affixed to the first and second clasping members.

18. The stylus holding apparatus of claim 10, wherein the first and second device clasps are U-shaped.

19. The stylus holding apparatus of claim 10, wherein the first and second clasping members have a width of half of an inch.

20. A stylus holding apparatus comprising:
a first clasping member made of a stiff, elastically deformable material, the first clasping member comprising:
a first device clasp comprising two fingers, wherein the first device clasp is U-shaped and the two fingers are outwardly slanted;
a stylus clasp, wherein the stylus clasp is C-shaped, wherein the stylus clasp comprises an opening, and wherein the stylus clasp is on an opposing side of the first clasping member relative to an opening of the first device clasp;
a second clasping member a stiff, elastically deformable material, the second clasping member comprising a second device clasp, the second device clasp comprising two fingers, wherein the second device clasp is U-shaped and the two fingers are outwardly slanted; and
a band, wherein the band is affixed to the first clasping member and the second clasping member, and wherein the opening of the stylus clasp is on an opposing side of the first clasping member relative to the affixment between the band and the first clasping member.
